(19) United States
(12) Patent Application Publication
(10) Pub. No.: US 2022/0138684 A1
(43) Pub. Date: May 5, 2022

(54) Automated Bill of Materials

(71) Applicant: Troy Aaron Harvey, Brighton, UT (US)

(72) Inventor: Troy Aaron Harvey, Brighton, UT (US)

(73) Assignee: PassiveLogic, Inc., Salt Lake City, UT (US)

(21) Appl. No.: 16/949,435

(22) Filed: Oct. 29, 2020

(51) Int. Cl. G06Q 10/08; G06Q 10/10; G06Q 50/16; G06Q 50/08; G06Q 30/02; G06F 30/13

(52) U.S. Cl. CPC G06Q 10/0875; G06Q 10/10; G06F 30/13; G06Q 50/08; G06Q 30/0206; G06Q 50/165

(57) ABSTRACT

A bill of sale is created as part of a design process that creates a copy of the building to be designed within a controller system that will also be used to control the electrical devices in the eventual building. When the entire design process is created within a single platform, the design itself can be used to generate the bill of materials. Integrated information about local suppliers, including currently-available inventory allows invoices for specific suppliers to be created.

### COPYRIGHT AUTHORIZATION

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF INVENTION

The present disclosure relates to creating bills of sale. More specifically, bills of sale are automatically generated as part of a model-based design process.

### BACKGROUND

Almost all building controls today are model-free. The model-free approach, while simple to implement, becomes quite difficult to manage and optimize as the complexity of the system increases. It also lacks the inherent self-knowledge to provide new approaches to programming, such as model-driven graphical programming, or to govern the interconnections between components and sub-system synergistics. Digital model based approaches to date have been limited in scope and specific to known models defined a-priori. They have thus lacked the ability to understand the connections between the various portions of a building project, and therefore find it very difficult to create a bill of materials automatically as part of the design process. Furthermore, more complex building controls generally require internet access which leaves the buildings prone to malfunction when outside networks go down, and high latency times even when outside networks are behaving as expected. This can lead to problems with desired building behavior.

### SUMMARY

This summary is provided to introduce a selection of concepts in a simplified form that are further described below in the Detailed Description section. This summary does not identify required or essential features of the claimed subject matter. The innovation is defined with claims, and to the extent this Summary conflicts with the claims, the claims should prevail.

In general, one innovative embodiment comprises receiving a building plan into a computer system with a processor, memory, and user interface. The computer system has, within memory, a plurality of predefined device types, a wire type, and a controller type. An instance of the device type is then placed within the building plan, or is already known. A controller type is chosen by a user or is already known. The computer system uses at least a portion of the building plan, the device instance, the location of the device instance, and the controller instance to create a partially finished building diagram. Using the partially finished building diagram, the computer system generates a wiring diagram that connects the controller instance to the device instance within the partially finished building diagram, the wiring diagram comprising wire lengths and wire locations within the building plan. The computer system can then use information found on the wiring diagram to generate a bill of materials.

In some embodiments generating the bill of materials further includes generating installation labor times or installation material requirements. The labor times may be priced, and the price may scale with quantity. Material requirements may also include price, and the price may scale with quantity. Some embodiments include a parts list. This parts list may include at least one of a device supplier, wire lengths from the wiring diagram, a wire supplier, or wire cost.

In some embodiments, a controller with a user interface may be used to input the building plan. The controller may house the computer system with a processor and memory. The controller may also be used to input the location of the device instance, as well as choosing the device instance type. This controller may then be used to generate the bill of materials.

In some embodiments, the controller is connected to a database associated with one or more suppliers. A user may be able to determine if a suppler has sufficient materials for the parts requested on the bill of materials. The user may be able to write a bill of sale for the given supplier, and change the inventory of the supplier to reflect the amount of goods that the user wishes to purchase.

### BRIEF DESCRIPTION OF THE FIGURES

FIG. 1 is a functional block diagram showing an exemplary embodiment of a controller within a physical space in conjunction which some described embodiments can be implemented.

FIG. 2 is an exemplary screen shot of an exemplary bill of materials in conjunction with which some described embodiments can be implemented.

FIG. 3 is an exemplary flowchart in conjunction with which some described embodiments can be implemented.

FIG. 4 is a screenshot embodiment that shows predefined devices with which some described embodiments can be implemented.

FIG. 5 is a screenshot embodiment that shows device inputs with which some described embodiments can be implemented.

FIG. 6 is a screenshot embodiment that that can be used to place a device instance within a building plan with which some described embodiments can be implemented.

FIG. 7 is a screenshot embodiment that can be used to place or view a controller instance within a building plan with which some described embodiments can be implemented.

FIG. 8 is a screenshot embodiment that can be used to constrain controller placement with which some described embodiments can be implemented.

FIG. 9 is a diagram that shows some differences between Euclidean and Manhattan distance measurements.

FIG. 10 is a functional block diagram showing an exemplary device type embodiment in conjunction which some described embodiments can be implemented.

FIG. 11 is a functional block diagram showing an exemplary parts list embodiment in conjunction which some described embodiments can be implemented.

FIGS. 12-14 are exemplary screen shots of exemplary bills of materials in conjunction with which some described embodiments can be implemented.

FIG. 15 is an exemplary diagram of a relationship between a controller and a supplier in conjunction with which some described embodiments can be implemented.

FIG. 16 is a screenshot embodiment of an exemplary equipment schematic with which some described embodiments can be implemented.

FIGS. 17-18 are exemplary screen shots of exemplary controller network schematics in conjunction with which some described embodiments can be implemented.

### DETAILED DESCRIPTION

Disclosed below are representative embodiments of methods, computer-readable media, and systems having particular applicability to systems and methods for automated point mapping generation. Described embodiments implement one or more of the described technologies.

Various alternatives to the implementations described herein are possible. For example, embodiments described with reference to flowchart diagrams can be altered, such as, for example, by changing the ordering of stages shown in the flowcharts, or by repeating or omitting certain stages.

### Overview

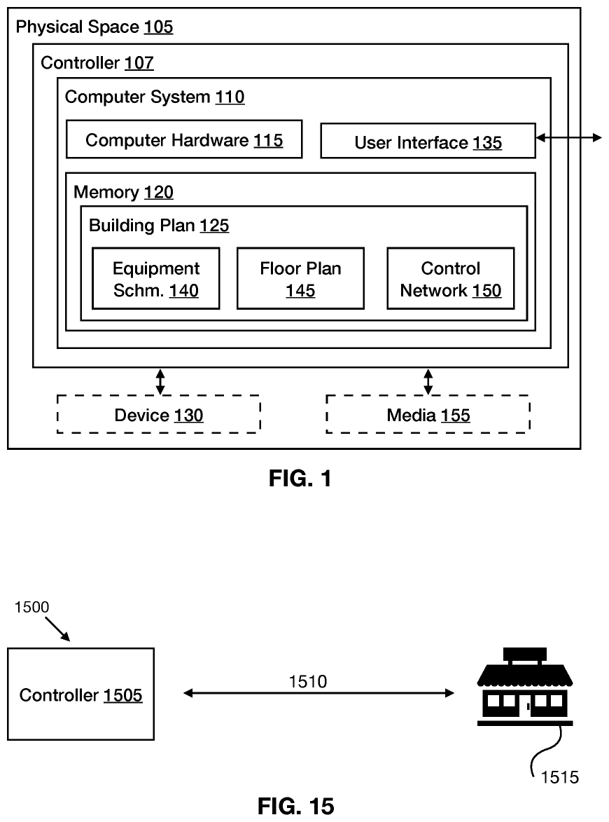

With reference to FIG. 1, in some embodiments, a building plan 125 is found in memory 120. The building plan may be previously created and input into the controller 107 using a user interface 135 or another input method. In some embodiments a building plan may be created using the controller 107 or a similar controller. The building plan includes at least one of a floor plan 145 of the physical space 105; an equipment schematic 140 that shows devices that are to be used in the building, and locations of the devices in the building; or a control network 150 that shows the connections between a controller and the devices it controls. In an exemplary embodiment, the building information is input into the controller. In another exemplary implementation, the building information is input into the controller using a wysiwyg interface; in yet other implementations, a mix of sources are used to input the building information into the controller. The building plan 125 may also comprise a control network schematic which describes at least one of how the device pins are connected to the controllers, the device pin requirements, the device pin protocol, and other information needed to properly wire the devices to the controllers. The control network schematic may also comprise the locations of the controllers, and a wiring diagram showing the locations of the wires within the building that connect the device(s) to the controller(s).

The controller may also have residing within memory a model that can be used to help the controller determine how to effectively control the physical space 105 the controller 107 is controlling. This model may be a thermodynamic model, a heterogenous neural network, a thermodynamic model representing a space, a thermodynamic model representing devices in the space, a model representing desired comfort in the space, and so on. The controller may be able to run the model, may be able to run the model by divvying up the model among several controllers, or a different way.

In some embodiments, a bill of materials (BOM) can be created using at least a portion of the building plan 125 that has been created. In some instances, this bill of materials includes the price. This model may have been created using a controller and the model may be stored on the controller. The bill of materials may be created by the controller. The term “bill of materials” is used as understood by one of normal skill in the art; it can be thought of as an inventory of the materials at a given level need to create something What the specific levels are called are industry dependent, but may include number of assemblies, systems, subsystems, components, parts, and components needed to build a structure, portion of a structure, subsystem of a structure, etc. One or more of the cost, cost type, cost version, subsystem level, etc., description, type, part number, sku, quantity, subcontracting, overhead cost, labor level, or labor amount, may also be included. The specific supplier may be included, as well as supplier location, and other information deemed useful. Some prices may scale with quantity. These quantity scales might also be included.

The technical character of embodiments described herein will be apparent to one of ordinary skill in the art, and will also be apparent in several ways to a wide range of attentive readers. Some embodiments address technical activities that are rooted in computing technology, such as, determining what materials are required for a given project, where controllers should go for various optimizations, more efficiently creating wiring diagrams for the controllers, and then automatically generating bills of material to provide the material necessary for such installations. This, in turn, makes constructing buildings and similar structures much easier, as inventory can be automatically checked, and bills of material can be automatically sent to the correct suppliers, saving the time that would otherwise be spent chasing down parts and materials. Other advantages based on the technical characteristics of the teachings will also be apparent to one of skill from the description provided.

### Systems

With continuing reference to FIG. 1, a system is shown that may be used, in whole, or in part, in any of the embodiments disclosed herein. The system comprises a physical space 105 which may have a controller 107 within it In some embodiments, the physical space 105 is proposed, and the controller is the same type of controller that will eventually be deployed within the actual physical space 105 when the proposed building is build. This controller 107 is an electrical controller that can connect to devices 130. Through these connections the controller 107 can control and record values of the devices 130. Some devices 130 may be connected to the controller 107 through a hard-wired system, while some may be connected through a wireless connection, and some may have both hard-wired and wireless controls. The controller 107 has a computer system 110 deployed within it In some embodiments, multiple controllers 107 are connected using a distributed computer system, such that the multiple controllers are connected by a local network but run as a single system. In such systems, one controller 107 may be selected by the working controllers 107 to be the master controller. If the master controller has problems, such as network connectivity problems, the remaining controllers can select a new master controller. In such situations, these controllers 107 are therefore edge computing devices with low latency such that processing is done locally. These controllers 107 also do not require an outside network connection for the system to run. If a single controller is used to run devices in a physical space it is also an edge computing device as it can control its devices without access to a cloud or an outside network connection.

The computer system 110 comprises computer hardware 115, and a memory 120. The hardware 115 comprises at least one processing unit. The processing unit executes computer-executable instructions and may be a real or a virtual processor. In a multi-processing system, multiple processing units execute computer-executable instructions to increase processing power. The memory 120 can be any appropriate volatile or non-volatile storage subsystem. For example, the external memory can be volatile memory, e.g., static memory cells, as in FPGAs and some CPLDs; or non-volatile memory, e.g., FLASH memory, as in some CPLDs, or in any other appropriate type of memory cell. The memory itself may have within it a model of the physical space 105. The controller 107 also has one or more devices 130 associated with it. These devices may be any sort of device that can connect to a controller in a building, as know to those of skill in the art. These may include HVAC equipment, security equipment, entertainment equipment, irrigation equipment, and so on.

The devices may be sensors, which may indicate information about a specific device; or may give information about state of the physical space 105, or some portion of the physical space 105. The devices may change state of the physical space 105, or a portion of the physical space. Example of state that can be modified by a device include temperature, humidity, noise levels, air flow noise levels, lighting levels, entertainment noise levels, CO2, VOC, and so on. Some of these devices may be connected by being physically wired to the computer system/controller 110, others may be connected by an interface network connection. This network connection may be a wired connection, such as an ethernet connection, or may be a wireless connection, or both. A user interface 135 is also included, which allows information to be input and output from the computer system/controller. The user interface may be a screen with a keyboard, a printer, a touch screen, a motion sensor, a 3-d input device that can be used to scan a space, such as a room; data may be input using a mouse, a voice-based command system, a touchscreen, a joystick controller, a pointing stick, a trackball, a wii remote, a digital camera, a digital camera with scanning software and/or hardware, a 3-d scanner, a barcode reader, etc.

The computing environment may have additional features. For example, the computing environment may include storage, one or more input devices, one or more output devices, one or more network components, such as network interface card, a wireless transceiver, a modem, a router, a wireless access point, etc. Other communication connections may also be included. An interconnection mechanism such as a bus, controller, or network interconnects the components of the computing environment. Typically, operating system software provides an operating environment for other software executing in the computing environment, and coordinates activities of the components of the computing environment. The storage may be removable or non-removable. In some embodiments the computing environment is networked together with no requirement for an outside network connection. This network connection may be entirely within the physical space 105.

The computer system 110, like other suitable systems, also includes one or more computer-readable storage media 155. Media 155 may be of different physical types. The media 155 may be volatile memory, non-volatile memory, fixed in place media, removable media, magnetic media, optical media, solid-state media, and/or of other types of physical durable storage media (as opposed to merely a propagated signal). In particular, a configured medium 155 such as a portable (i.e., external) hard drive, CD, DVD, memory stick, or other removable non-volatile memory medium may become functionally a technological part of the computer system when inserted or otherwise installed, making its content accessible for interaction with and use by central processing unit within the hardware 115. The removable configured medium 155 is an example of a computer-readable storage medium 155. Some other examples of computer-readable storage media 155 include built-in RAM, ROM, hard disks, and other memory storage devices which are not readily removable by users. Neither a computer-readable medium, nor a computer-readable storage medium nor a computer-readable memory is a signal per se.

### Bill of Materials

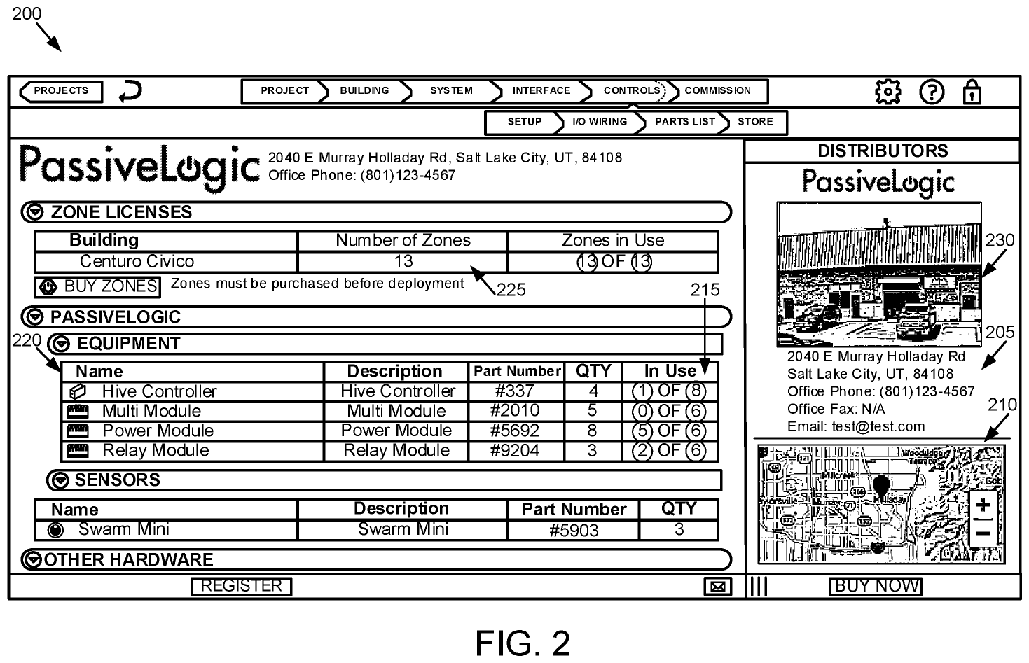

An exemplary embodiment of a generated bill of materials is shown with reference to FIG. 2 at 200. Information about the building, such as the number of zones 225 can be shown. Zones may be defined areas of the building. Devices may be associated with a zone or multiple zones. The exemplary embodiment shown herein indicates that the building has one zone. Other building information can be shown or referenced such as a site description (what type of building, how much is above ground, how much is below ground, the different mechanical and other systems (such as humidity, HVAC, storing of temperature sensitive materials), etc. This information may be stored in memory 120, and/or may be input by a user using the controller 107.

Name of a part 220, description of the part, the part number, and the quantity are shown in this exemplary embodiment under an “equipment” heading or a “sensor” heading. Other headings are also envisioned. In some embodiments (not shown), price may also be shown. Some parts themselves can comprise slots for other parts. For example, in some embodiments, a controller has some number of slots for modules that plug into the controllers. The device wires directly into a terminal on the module. The module then sends signals from the controller 107 to the device 130, and vice-versa. Some modules may have processors and memories of their own that allow them to modify the signal to and from the controller and/or to and from the device 130. To signify the module-controller relationship, the chosen controller (a “hive” controller 220) has an “In Use” column 215 which tells how many total modules have been accounted for within the current plan, as reflected in the parts list. In this example, the column says “1 of 8,” which indicates that one module of eight total modules possible to fit in the controller are being used. In this illustrative embodiment, a “motor” module has six wire attachment locations. The motor module description line says “2 of 6” in the “In Use” 215 column. This indicates that there is room for 6 wires to be attached to devices in the motor module, 2 of which will be used in the current installation.

The bill of materials may be divided into logical subgroups. For example, parts may be grouped by supplier, by part type, by cost, by availability, by distance from a location, and so on.

When the bill of material (BOM) is grouped by supplier, information about the supplier may be displayed 205. This information may include address, a map showing the location of the supplier 210, a picture of the location 230, email information, phone number, fax number, and so on.

The bill of materials may be displayed on a user interface 135 display device such as a computer screen, may be printed out, may be saved to a computer file, may be sent by email to the supplier, may be faxed, etc. The bill of materials display may be by system, subsystem, or by another grouping.

The bill of materials may be in a form that can be used to purchase the supplies from the supplier, such as an invoice. A method to send the bill of materials directly to the supplier or to an intermediary that will then contact the supplier may also be included. This may include sending the bill of materials by mail, by fax, by email, etc.

### Methods

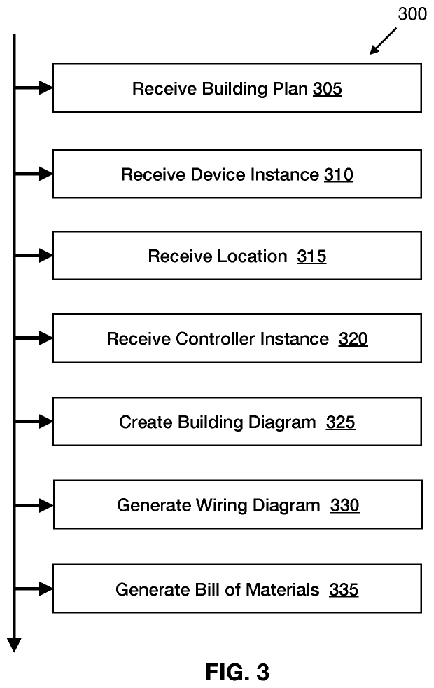

With reference to FIG. 3, at 300 a method to generate a bill of material is described. Technical methods shown in the Figures or otherwise disclosed will be performed automatically, e.g., by a computer system 110 which might be part of a controller 107. A human user may launch a program stored in memory 120 to create a bill of materials 200, leading to a mix of manual and automatic actions, although no entirely manual methods are contemplated herein. Steps in an embodiment may also be done in a different order than the top-to-bottom order that is laid out in FIG. 3. Zero or more illustrated steps of a method may be repeated, maybe with different building plans, device instances, locations, and so forth. Steps may be performed serially, in a partially overlapping manner, or fully in parallel. In particular, the order in which the flowchart 300 is traversed to indicate the steps performed during a method may vary from one performance of the method to another performance of the method. The flowchart traversal order may also vary from one method embodiment to another method embodiment. Steps may be omitted, and/or repeated. Steps may also be performed on one or more controllers that use a distributed operating system to communicate, or otherwise depart from the illustrated flow, provided that the method performed is operable and conforms to at least one claim.

At 305, a building plan is received into a computer system with a user interface, such as that shown with reference to FIG. 1. The building plan may be received by being drawn using the user interface 135, may be imported from an existing CAD model, may be scanned into the computer using a 3-d scanner; may be scanned and then imported into the computer, or any other method may be used known to those of skill in the art. The computer system comprises some number of predefined device types stored in memory 120. These predefined device types may be a computer model of a piece of equipment, a sensor, or some other type of device. They may also comprise the size of the device, the wiring protocol, the number and types of wires that will be used to wire the device to a controller, the cost, specifics on how the device works, and so on. The computer model also comprises at least one controller type. This controller represented by the controller type may be operationally able to control controllable equipment and sensors. It may be an HVAC control system, a building automation system, an irrigation system, etc. The controller type may comprise the location of the controller, the number of terminal connectors, the types of terminal connectors, and so on. It may also comprise the instances of a predefined device type that is associated with specific wiring terminals. The controller type may also comprise information about modules that the controller may use.

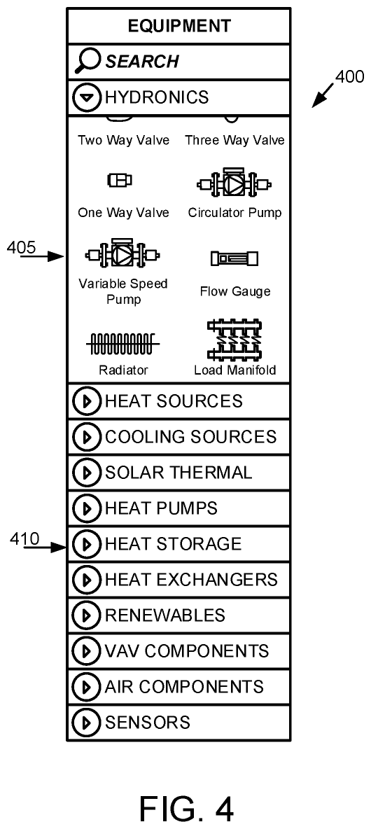

In some embodiments, at 310, a device instance is received. This device instance may be received by a user selecting it from a list of the predefined device types on the computer system interface, or the device instance may be input in a different way, such as being stored on a computer-readable medium, and read directly into the computer. A screenshot embodiment that shows predefined devices is shown in FIG. 4 at 400. Individual predefined device icons 405 can be displayed, and chosen by a user. Different sorts of devices (such as heat sources, cooling sources, solar thermal, heat storage etc.) can be found by selecting different drawers 410.

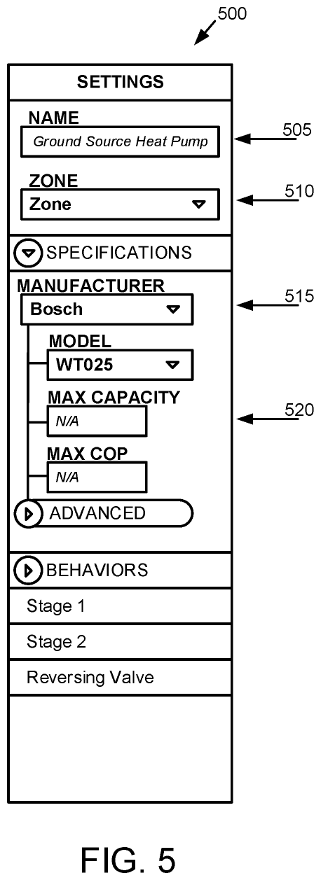

The predefined device type definition may include wiring information. The device instance may be sent through an internet connection to the computer, etc. If the device type of the device instance has not been previously defined, the computer system may allow the new device type to be defined. Once the system knows about the device type, an instance of that device type may be received. A screenshot embodiment that shows user ability to define devices is shown in FIG. 5 at 500. A name can be input at 505. A zone in a building that has predefined zones can be chosen at 510. A manufacturer and model can be input at 515. Other information such as maximum capacity, and other information associated with the type of device can also be input at 520. Device behaviors 525, which may be described using physics equations, such as how the device changes state of a space around it, may be input. In some embodiments, a wire type is received. The wire type may be associated with a device type or may be separate. The wire type is the type of wire that will be used to wire the device to the controller. In some instances, multiple wire types may be used for a single device.

In some embodiments, at 315, a location of the instance within the building plan is received. This location may be received along with the device instance or may be sent separately. In some embodiments, at 320, a controller instance is received of one of the controller types that are a part of the system. If the controller type has not been previously defined, the computer system may allow the new controller type to be defined. Once the system knows about the controller type, an instance of that controller type may be received.

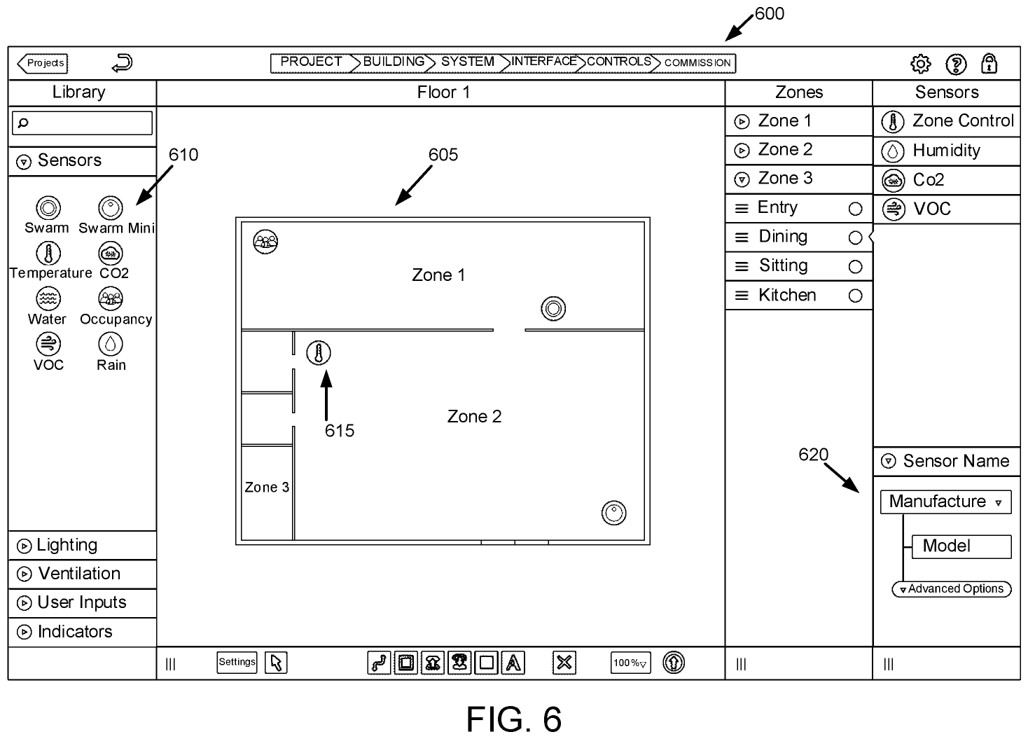

FIG. 6 shows a user interface that can be used to place a location instance within a building plan. An exemplary screen display 600 is shown that allows a user to select a predefined device instance, in this exemplary instance, a sensor. A portion of a floor plan 145 is shown at 605. Floor plan representations displayed may include some combination of walls, floors, doors, windows, and other building features. At 610, a list of predefined devices (e.g., sensors) are displayed. A user can choose a sensor and then drag or otherwise place it 615 in a specific location within a floor plan 605. In some embodiments, a user may input a new device model using software and I/O associated with the controller, such as with an interface 620, which allows a user to input, e.g., a manufacturer, a model, and other information which may comprise specific information about how the unit model behaves. After inputting the new device instance, the device instance may be added to the list of predefined device instances.

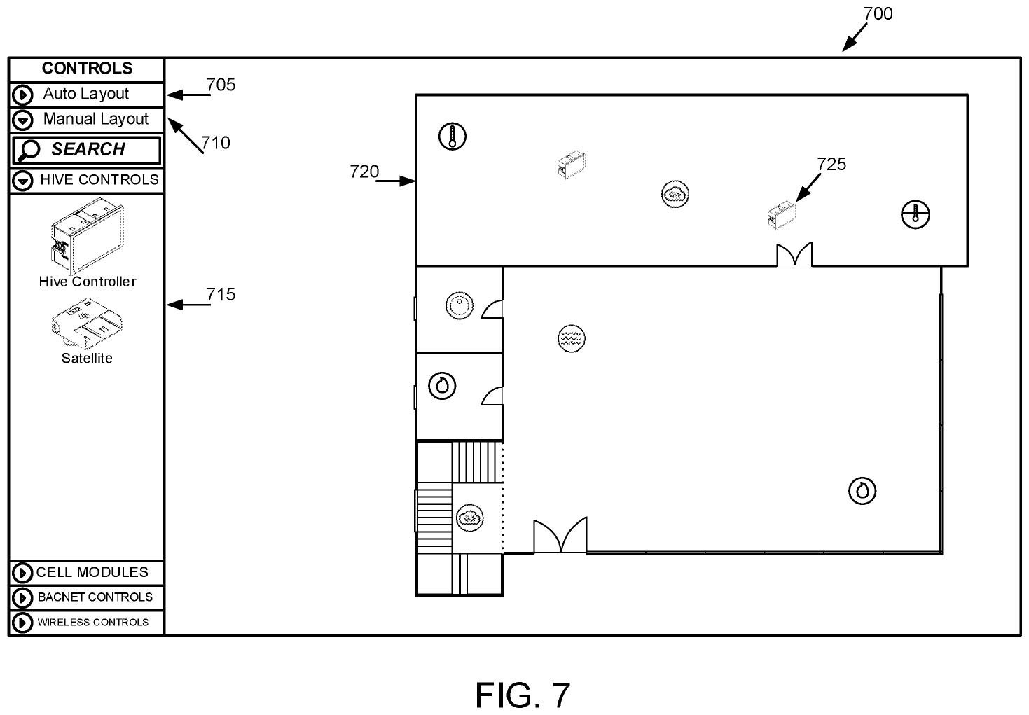

In some embodiments, a controller instance is received 320. The controller instance may be the type of the controller 107 that the bill of materials may be generated on. FIG. 7 shows an exemplary user interface 700 that can be used to receive a controller instance, or view a controller instance that has been received. A controller instance can be placed (or received) automatically 705 by, in this instance, choosing “Auto Layout.” In such a case, when the controller is placed automatically, the location of the controller can be viewed 725 on a panel 720. A controller instance can be placed manually at 710. If a manual controller instance is chosen, then a controller type can be chosen by selecting a controller type at 715. A controller instance of that type can then be dragged to a location 725 on a displayed floor plan 720.

In some embodiments, at 325, the computer system creates a building diagram using, e.g., at least a portion of the building plan, the device instance, the location of the device instance, and the controller instance. This building diagram may be partially finished. This building diagram includes the locations of the device and the controller within the building.

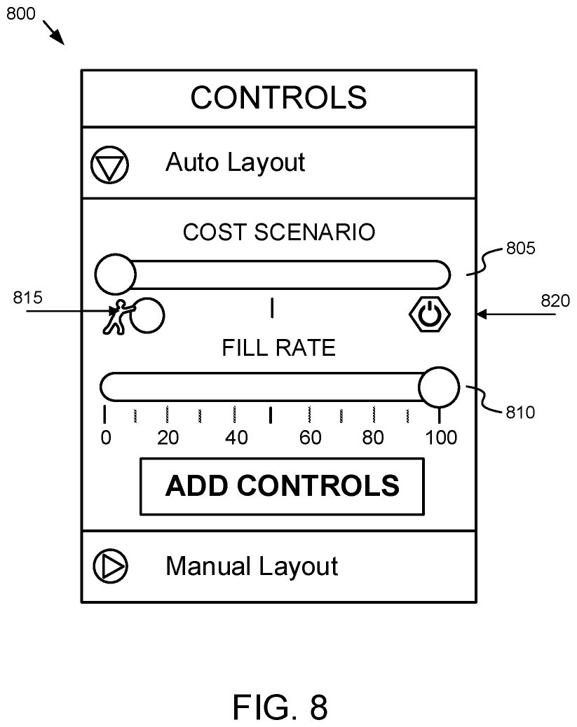

FIG. 8 shows an exemplary screenshot 800 that can be used to designate how a building diagram can be built. In an embodiment, a controller constraint can be chosen by a user. Controllers can be wired to some number of devices (e.g., equipment, resources, sensors, etc.) depending on how many wires the devices have and how many terminal wire connectors the controller has. A building may require multiple controllers to accommodate the devices that need to be controlled. The optimal locations of the controllers can be chosen automatically. “Optimal” does not mean absolutely best, but rather a good location based on various constraints. The exact amount of optimality depends on the specific algorithms used. How many controllers are used, and where they are placed can be modified by the user by selecting constraints. Common constraints are equipment cost vs. labor cost, and controller fill rate vs. controller cost, and so on. In an exemplary embodiment, the cost scenario slider shown at 805 goes from high labor costs (indicated by the icon of a human rolling a large ball 815) to high equipment costs (indicated by the icon of a power switch 820). A user can accept a constraint by setting the slider to a value between high labor cost and high equipment cost. When higher labor cost is chosen, the number of controllers is minimized, as fewer controllers will be used, but the devices will be further from their controller. This increases the average length from the controller any given piece of equipment is, requiring more labor to install.

In some embodiments, fill rate indicates how full each of the controllers should be, which may be listed in percentages, (0, 20, 40, . . . 100) as shown at 810, though other methods are envisioned, as well. A high fill rate saves money on controllers, but most likely raises installation costs, as, on average, the controllers will be further from the devices they will be wired to. When a low controller fill rate is chosen, such as 40%, the controllers may be closer to the devices they will control. There is also more room for future devices to be added to the controller, thus minimizing new controller installation costs.

These choices affect the number of controllers that will be needed to create the building diagram, and the location of the controller(s) within the building diagram.

In some embodiments, at 330, the computer system generates a wiring diagram that connects the controller instance to the device within the partially finished building diagram. At a minimum, the wiring diagram comprises the wire lengths, and/or the location of the wiring in the partially finished building diagram. Because the computer system 110 knows where the device(s) and the controller(s) are, and what the device wiring requirements are within the building, the computer can determine how to route the necessary wires in the building between the device and the controller, using methods well-known to those of skill in the art.

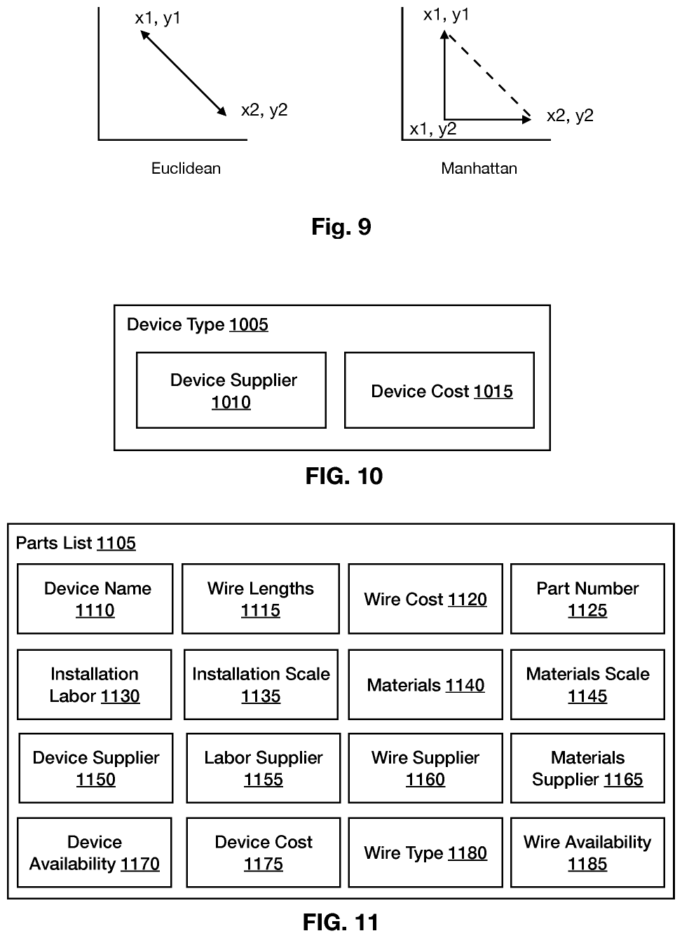

In some embodiments, wiring distances within the building are determined using, at least in part, a Manhattan distance algorithm formula, also called taxicab geometry. Manhattan distance is conceptually thought of as the distance between two points that a taxicab would travel in Manhattan, turning at 90° around the city blocks to get from point A to point B. With reference to FIG. 9, on a plane, Manhattan distance is the distance between two points measured along coordinate (which may be right angle) axes. When the first point is (x₁, y₁) and the second point is (x₂, y₂), then the Manhattan distance 910 is |x₁−x₂|+|y₁−y₂|, while the Euclidean distance 905 is \sqrt{(x₁−x₂)²+(y₁−y₂)²}. The floor plan 145 may comprise location of walls. The building plan also comprises location of equipment, and location of the controller(s). Obstacles to wiring may also be included in the floorpan 145 or elsewhere within the building plan 125. The wiring distances may be determined by using a Manhattan distance formula with walls and other obstacles as portions of the coordinate system.

In some embodiments, at 335, the computer system generates a bill of materials comprising the device, wire lengths, and a wire cost. The bill of materials may also generate other parts that could be used to wire the physical building. A sample bill of materials can be seen with reference to FIG. 2 and the surrounding text.

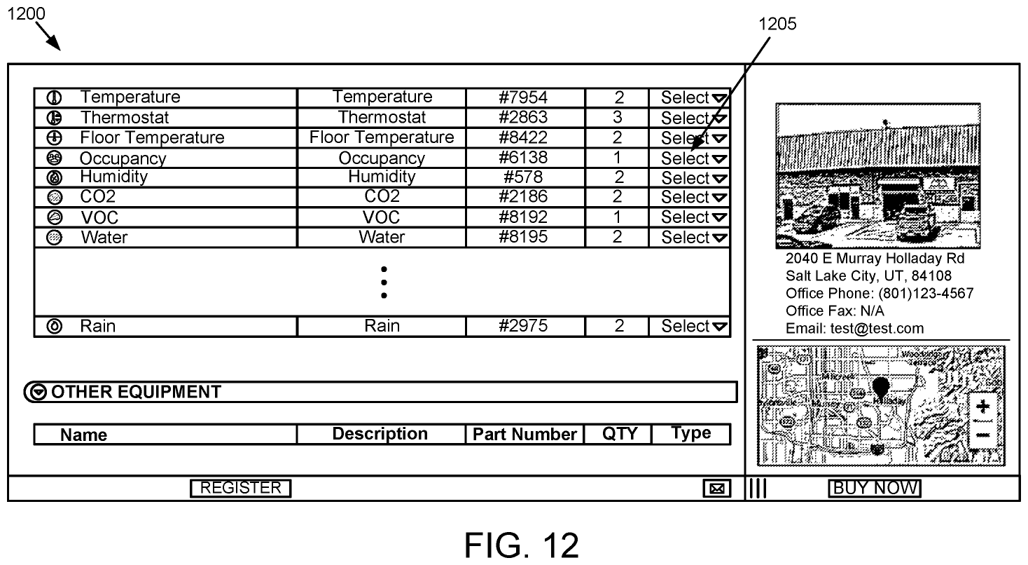

With reference to FIG. 10, a device type 1005 may comprise a device supplier 1010 and/or a device cost 1015. This allows the bill of materials generated at 335 to also include the supplier at which the part may be purchased, and what it will cost. Other information, such as location, inventory at the supplier, discounts available, backorders, etc., may also be included in the device type and may also be included on the bill of materials. In some implementations, there may be multiple suppliers that can supply a part that will be displayed. A user can then choose the desired supplier based on cost, availability, distance, etc.

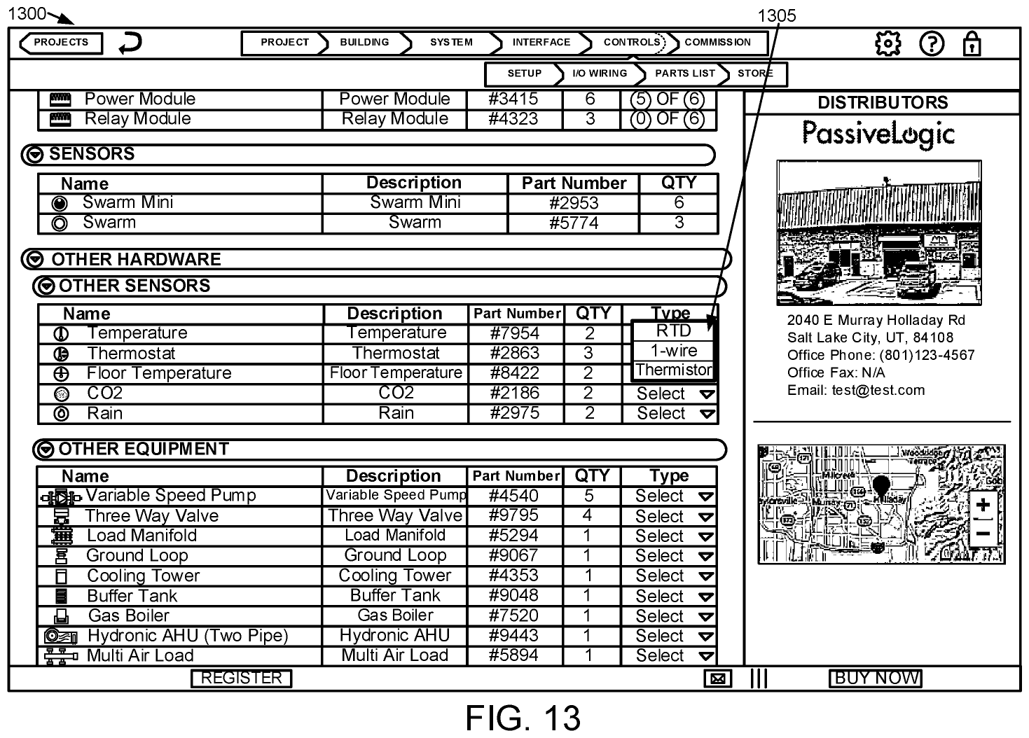

With reference to FIG. 11, the bill of material may also comprise a parts list 1105. The parts list may comprise a device name 1110, wire lengths 1115 needed for installation of the device, part number 1125, wire type 1180, wire cost 1120, an/or device cost 1175. The system may understand how much wire is on a wire spool, and so can do the calculation about how many spools need to be purchased. Some devices require different types of wire; this can also be calculated such that the parts list has types of wire, part number, and number of those parts that is needed. Some installations may have multiple types of wires for a single device.

Installation labor costs 1130 may also be determined automatically, based on features of the building plan that may require extra work, the amount of work needed to install the device, and the amount of work needed to wire the device to the controller. This labor cost may comprise an installation scale factor 1135, in that there may be different prices for labor depending on how much labor is required. Installation may also use other materials 1140, which can be tracked and included on a parts list. Material prices may also have a materials scale 1145, such that the price depends on the amount of materials that are used. This may also be stored in memory, placed in the parts list, and/or included on the bill of materials. Different devices may have different suppliers. The parts list may also include a device supplier 1150 for each device with a separate supplier, one or more labor suppliers 1155, one or more wire suppliers 1160, and one or more materials suppliers 1165 for other material needed for installation.

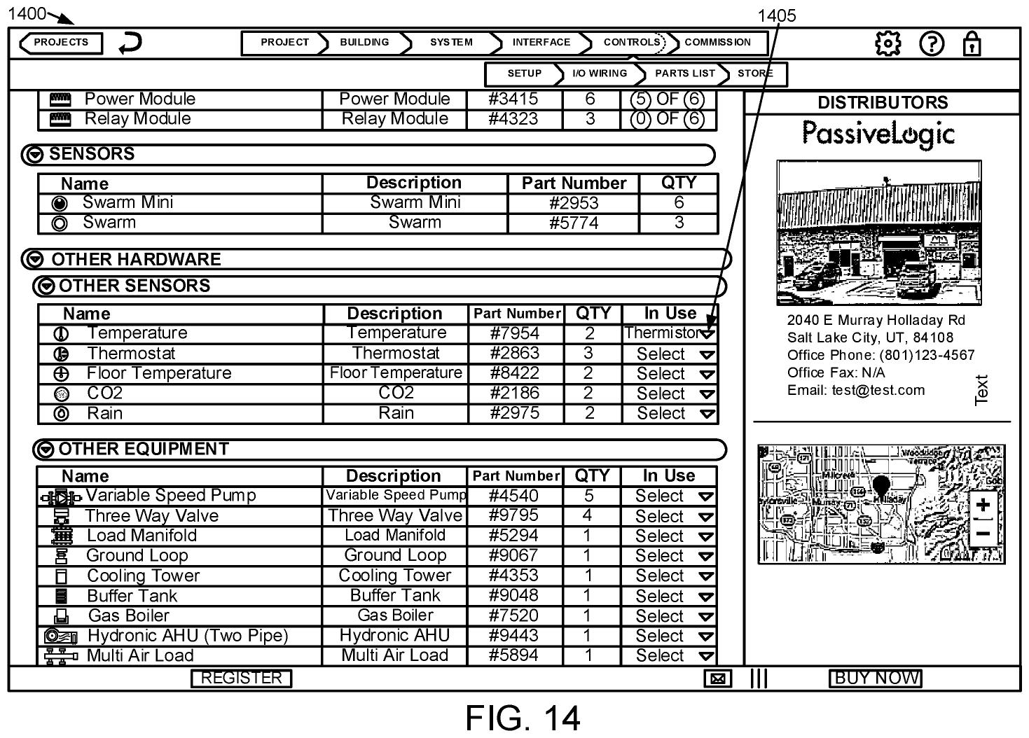

The process of building the bill of materials may allow the user to make decisions about what parts will be chosen. If several suppliers can provide the same part (for example), a list with information about them (such as cost, location, and other information) may be included. A user may be able to choose the desired supplier. If several different sorts of parts may be used, a user may be able to specify which sort to choose, or choose several of one, and several of another. With reference to FIG. 12, in some embodiments, a parts list when first generated has some options that a user can still select. This can be seen in the exemplary parts list shown at 1200, which lists sensors to be used for a physical space 105. The “type” column 1205 reads “select,” indicating that the more than one type of the device (in this case a sensor) chosen is available.

With reference to FIG. 13 at 1300, in an implementation, selecting a location within the type column location displays a drop-down menu 1305 with the options available. In this example, the choices are “RTD”, “1-wire”, and “Thermistor”. Other implementations use other methods known to those of skill in the art to choose a selection from a series of choices. With reference to FIG. 14 at 1400, when a selection is chosen, the chosen selection appears in the column location 1405, where the “type” column value now reads “Thermistor”. This part will therefore have a Thermistor type of resistor, and associated wiring type.

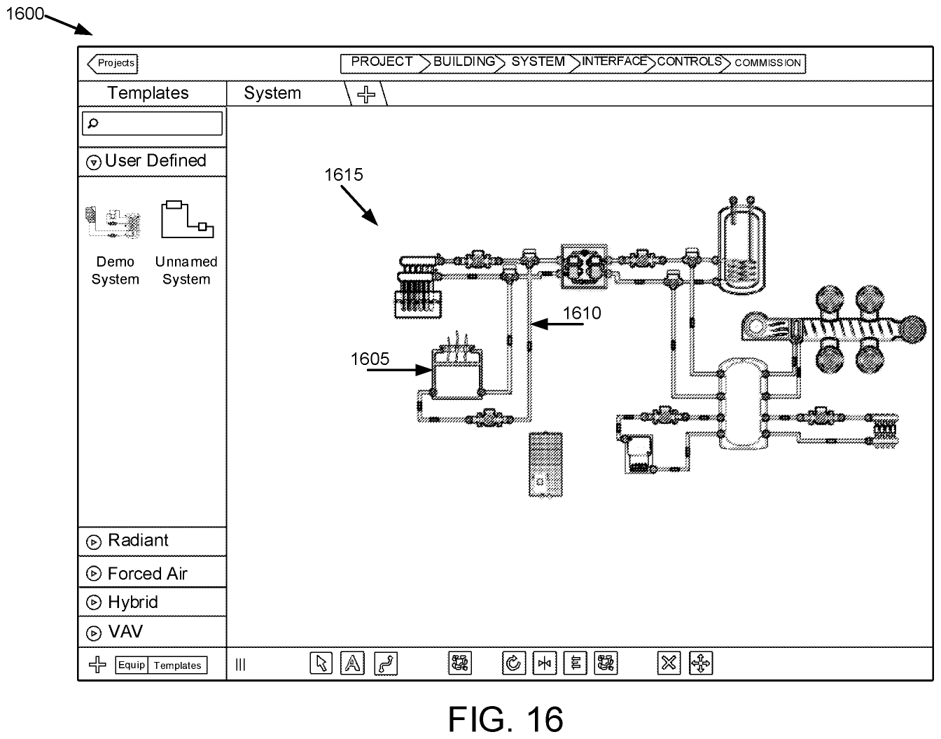

With reference to FIG. 15 at 1500, in some embodiments, a connection 1510 exists between a supplier 1515 and the controller 1505. This might be a network link 1510 that provides direct access to a supplier inventory, a browser-based link, etc. The generation of the bill of materials may check supplier inventory prior to suggesting a supplier, or may allow a user to view available inventory, such as device availability 1170, and choose which supplier to use. The automatic generation portion may automatically check device availability 1170, wire availability 1185, installation labor ability, materials availability, etc., and only include suppliers on the list with availability. Wire ability, materials availability, and labor availability, similarly, may also be checked. In some instances, suppliers with availability are automatically chosen. The generation of the bill of materials may automatically debit a given store's inventory when parts from it are chosen. Generation of the bill of materials may also choose the least expensive part from a list of suppliers, or may choose a part from a list of suppliers on another criterion, such as distance from the physical space 105, favored supplier, availability of a discount, etc.

### Schematics

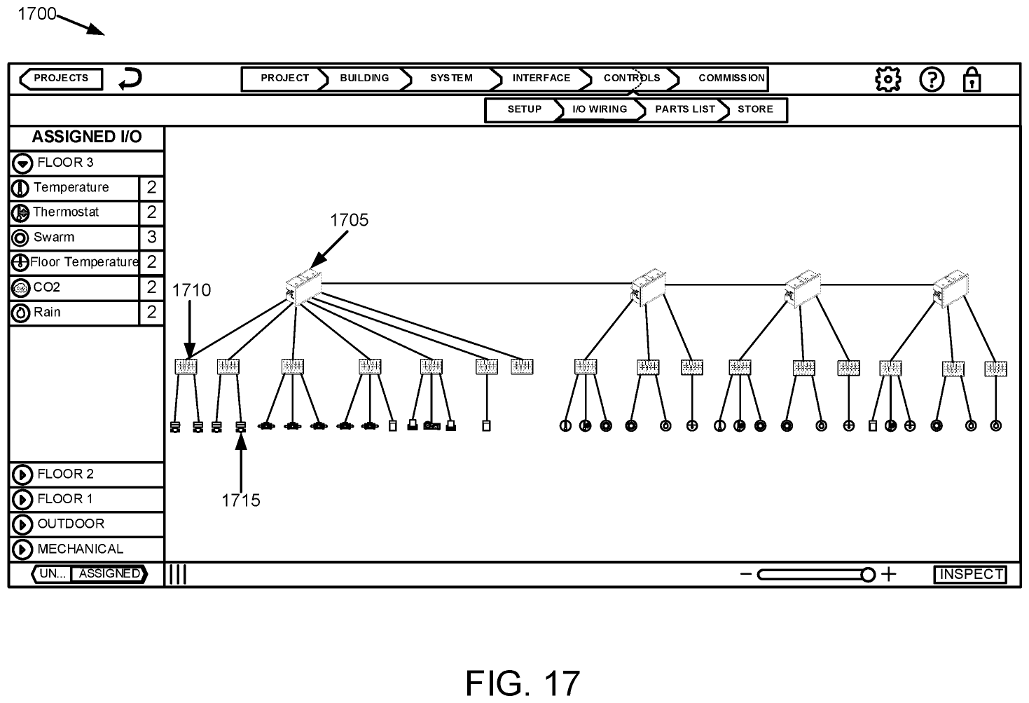

With reference to FIG. 16, in some embodiments, a device instance is associated with an equipment schematic 1600. This equipment schematic defines how the different equipment systems work together. The devices 1605 and the connections 1610 between different devices are shown on a system screen 1615. This allows the computer system 110 to determine what connectors, tubing, pipes, etc., are needed between different device portions for installation.

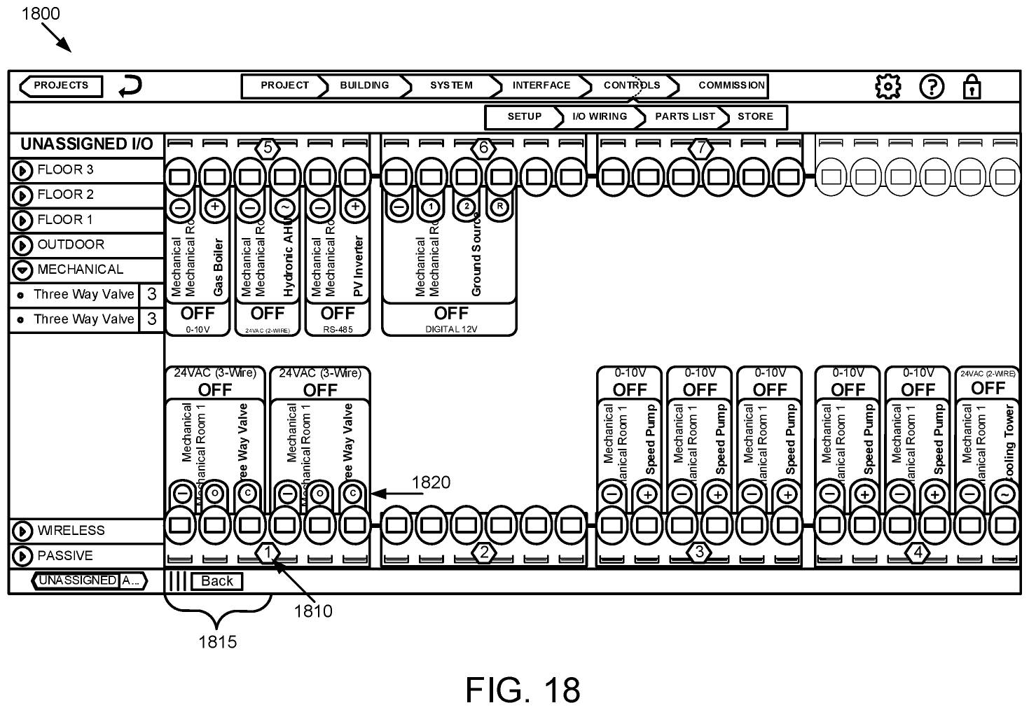

With reference to FIG. 17, an exemplary controller network schematic is shown. For a controller system, each controller 1705 is shown. A controller, in this embodiment, has a number of associated modules 1710. The devices 1715 that are wired to modules are shown attached to their associated module. With reference to FIG. 18, in some implementations, the controller network schematic further comprises a more detailed drawing of the controllers 1800. The devices that are to be attached to the controllers are shown at the locations they will be attached. A Three Way Valve 1805 will be attached to the controller in a first module 1810, at the first, second, and third terminal blocks 1815. Other information, such as the terminal types 1820, may also be included. In some embodiments, the controller network schematics 1700, 1800, may be used to determine controller placement in a physical space 105, and controller-device wiring requirements.

In view of the many possible embodiments to which the principles of the disclosed invention may be applied, it should be recognized that the illustrated embodiments are only examples of the invention and should not be taken as limiting the scope of the invention. Rather, the scope of the invention is defined by the following claims. We therefore claim as our invention all that comes within the scope and spirit of these claims.

1. A method to generate a bill of material comprising:
receiving a building plan into a controller with a processor, memory, and user interface, the controller being a type of controller that will eventually be deployed within a physical space represented by the building plan, the building plan received into the controller using the user interface, the memory comprising:
a plurality of predefined device types,
a wire type,
a thermodynamic model that helps the controller determine how to effectively control the physical space, and
a thermodynamic model representing devices in the physical space;
the controller receiving a device instance of a device type;
the controller receiving a location of the device instance within the building plan;
the controller receiving a controller instance;
the controller using at least a portion of the building plan, the device instance, the location of the device instance, and the thermodynamic model that helps the controller determine how to effectively control the physical space, to create a partially finished building diagram;
using the thermodynamic model that helps the controller determine how to effectively control the physical space, the controller generating a wiring diagram that connects the controller instance to the device instance within the partially finished building diagram, the wiring diagram comprising wire lengths and wire locations within the building plan; and
the controller using the wiring diagram to generate a bill of materials comprising the device type, and the wire lengths;
wherein the wiring diagram is at least partially determined by application of a Manhattan distance algorithm to a portion of the building plan, the location of the device instance, and the location of the controller instance.

2. The method of claim 1, wherein at least a portion of the building plan comprises a floor plan, an equipment schematic, or a controller network schematic.

3. The method of claim 2, wherein the device instance is associated with the equipment schematic and wherein the location of the device instance and location of the controller instances are associated with the floor plan.

4. The method of claim 3, wherein generating the bill of materials further comprises generating at least one of installation labor times or installation material requirements.

5. The method of claim 3, wherein the device type comprises a device supplier, and further comprising a parts list that comprises the device supplier, the wire lengths, and a wire supplier.

6. The method of claim 3, wherein the device type comprises a device cost, and further comprising a parts list that comprises the device cost and the wire lengths.

7. The method of claim 5, further comprising a connection between the device supplier and the controller that informs the controller of device availability at the device supplier, and wherein the parts list further comprises device availability.

8. The method of claim 6, wherein the parts list further comprises installation labor cost and installation materials cost and wherein the installation labor cost scales with a first quantity and wherein the installation materials cost scales with a second quantity.

9. The method of claim 4, further comprising the controller determining a location of the controller instance, and wherein generating the wiring diagram further comprises generating the location of the device instance and the location of the controller instance.

10. (canceled)

11. The method of claim 5, where at least two device instances are received with different suppliers, and wherein generating the parts list comprises generating a separate parts list for each supplier.

12. A system which generates a bill of materials, the system comprising: a building plan, a controller, being a type of controller that will eventually be deployed within a physical space represented by the building plan, the controller comprising a processor; a memory in operable communication with the processor; a plurality of predefined device types, a wire type, and a controller type residing in the memory; a model that helps the controller determine how to effectively control the physical space; a thermodynamic model representing devices in the physical space, and a bill of materials generator including instructions residing in memory which are executable by the processor to perform a method which includes: receiving within the controller a device instance of a device type;
receiving within the controller a location of the device instance within the building plan;
receiving within the controller a controller instance of the controller type;
using at least a portion of the building plan, the device instance, the location of the device instance, the model that helps the controller determine how to effectively control the physical space, and the controller instance to create a partially finished building diagram;
using the thermodynamic model representing devices in the physical space to generate a wiring diagram that connects the controller instance to the device instance within the partially finished building diagram, the wiring diagram comprising wire lengths and wire locations within the building plan; and
within the controller, generating a bill of materials comprising a name of the device instance, and the wire lengths.

13. (canceled)

14. The system of claim 12, wherein the controller further comprises wherein the controller further comprises controlling instructions, and wherein the controlling instructions comprise a user interface, wherein the building plan comprises a floor plan, and wherein the floor plan is received into the controller using the user interface.

15. The system of claim 14, wherein the controller wherein the controller further comprises controlling instructions, and wherein the controlling instructions are operationally able to accept the location of the device instance within the building plan from a user using the user interface.

16. The system of claim 15, wherein the bill of materials is displayed on the user interface.

17. The system of claim 16, wherein the controller further comprises controlling instructions, and wherein the controlling instructions are operationally able to control a device of the device type.

18. The system of claim 15, further comprising using the building plan, the device instance and the location of the device instance to generate an equipment schematic that comprises a location of the controller.

19. The system of claim 18, further comprising using the building plan, the location of the controller, a schematic of the controller and a schematic of the device instance to generate a wiring diagram between the controller and a device represented by the device instance.

20. A computer-readable storage medium configured with software which upon execution within a controller deployed within a physical space represented by a building plan, the controller controlling at least one device within the building plan, performs a method of generating a bill of materials in an edge-computing environment, the method comprising:
receiving a building plan;
receiving a plurality of predefined device types;
receiving a wire type;
receiving an instance of a thermodynamic model that helps determine how to effectively control the physical space;
receiving an instance of a thermodynamic model representing devices within the physical space;
receiving a device instance of a device type;
receiving a location of the device instance within the building plan;
receiving a controller instance of the controller type;
receiving a location of the controller instance within the building plan;
using at least a portion of the building plan, the device instance, the location of the device instance, the instance of the thermodynamic model that helps the controller determine how to effectively control the physical space, and the controller instance to create a partially finished building diagram;
the thermodynamic model representing devices in the physical space generating a wiring diagram that connects the controller instance to the device instance within the partially finished building diagram, the wiring diagram comprising wire lengths and wire locations within the building plan; and
using the thermodynamic model representing devices in the physical space to generate a bill of materials comprising the device instance, and the wire lengths;
wherein the wiring diagram is at least partially determined by application of a Manhattan distance algorithm to a portion of the building plan, the location of the device instance, and the location of the controller instance.
